(19) United States
(12) Patent Application Publication
(10) Pub. No.: US 2024/0084453 A1
(43) Pub. Date: Mar. 14, 2024

(54) CARRIER DEVICE AND SEMICONDUCTOR PROCESSING EQUIPMENT

(71) Applicant: BEIJING NAURA MICROELECTRONICS EQUIPMENT CO., LTD., Beijing (CN)

(72) Inventors: Xu ZHU, Beijing (CN); Mingke YAO, Beijing (CN); Haiyun ZHU, Beijing (CN); Zhenguo MA, Beijing (CN); Yanbao WEI, Beijing (CN)

(21) Appl. No.: 18/516,653

(22) Filed: Nov. 21, 2023

Related U.S. Application Data
(63) Continuation of application No. PCT/CN2022/093044, filed on May 16, 2022.

(30) Foreign Application Priority Data
May 21, 2021 (CN) 202110560026.1

(51) Int. Cl. C23C 16/458; C23C 16/455; C23C 16/509; H01L 21/687

(52) U.S. Cl. CPC C23C 16/4585; C23C 16/45565; C23C 16/509; H01L 21/68735

(57) ABSTRACT

A carrier device in semiconductor processing equipment includes a base and an edge ring. The base includes a base body configured to carry a wafer and has an outer diameter smaller than a diameter of the wafer. The edge ring surrounds the base and has an outer diameter greater than the diameter of the wafer. An outer circumferential surface of the base body faces and is spaced from an inner circumferential surface of the edge ring to form a first annular channel. The first annular channel communicates with a gas supply system. When the base body carries the wafer, an upper surface of the edge ring faces and is spaced from a lower surface of the wafer to form a second annular channel. The first annular channel communicates with the second annular channel.

### CROSS-REFERENCE TO RELATED APPLICATION

This application is a continuation of International Application No. PCT/CN2022/093044, filed on May 16, 2022, which claims the priority of Chinese Patent Application No. 202110560026.1, filed on May 21, 2021, the entire contents of all of which are incorporated herein by reference.

### TECHNICAL FIELD

The present disclosure relates to the technical field of semiconductor manufacturing technologies and, more particularly, to semiconductor processing equipment and a carrier device of the semiconductor processing equipment.

### BACKGROUND

A Metal-organic Chemical Vapor Deposition (MOCVD) method shows good step coverage and resistivity characteristics in processes of forming a metal or metal nitride barrier layer and an adhesion layer. The MOCVD method has become an important method for implementing the processes of forming the barrier and the adhesion layer. MOCVD equipment also becomes mainstream equipment for integrated circuit manufacturing.

In the MOCVD method, a metal-organic compound is used as a source for metal or metal nitride. At a high temperature, the source undergoes a thermal decomposition reaction. By-products such as carbon, hydrogen, and oxygen are separated in a gaseous form. The metal or metal nitride deposits to form a thin film. The thin film formed by thermal decomposition includes many impurities. The resistivity of the thin film is high. The thin film needs to be processed using plasma to remove the impurities of the thin film to reduce the resistivity. To improve production efficiency, the MOCVD equipment for implementing the thin film preparation method needs to finish the thin film thermal deposition and in-situ plasma processing in the same chamber. The plasma is generated by radiofrequency (RF) capacitive-coupled discharge, which requires the chamber to satisfy both the flow field and thermal field requirements of the CVD process and the requirements of the RF system and prevent abnormal discharge.

During the film formation process, the MOCVD equipment needs to heat the wafer to a certain temperature to cause the source to be stably thermal-decomposed. Thus, the base for carrying the wafer needs to have a heating function. The base includes a heater. An edge ring is arranged around the base. An annular gap is arranged at the area facing the base and the edge ring to form an edge purge channel. When the wafer is placed on the base, the edge of the edge ring can block a part of the opening of the edge purge channel. During the thermal deposition process, gas passes the edge purge channel to blow the edge of the wafer. Thus, the thin film deposition is avoided on the back surface and side surface of the wafer, the temperature of the annular ring is reduced, and the thin film deposition at the surface of the annular ring is reduced. During the plasma processing process, gas does not pass through the edge purge channel. However, the channel communicates with the chamber. Charges are cumulated at the surface of the wafer prepared by an insulation material (a metal or metal nitride thin film is deposited on the base made of silicone oxide). The surface of the wafer has a high level. The base is grounded to be a zero level. Thus, the back surface of the wafer is prone to discharge or ignite in the edge purge channel in a plasma environment and a constant electric field, which affects the process stability and causes particle contamination.

### SUMMARY

One aspect of the present disclosure provides a carrier device in semiconductor processing equipment, including a base and an edge ring. The base includes a base body configured to carry a wafer. An outer diameter of the base body is smaller than a diameter of the wafer. The edge ring surrounds the base. An outer diameter of the edge ring is greater than the diameter of the wafer. An outer circumferential surface of the base body faces and is spaced from an inner circumferential surface of the edge ring to form a first annular channel. The first annular channel is configured to communicate with a gas supply system. When the base body carries the wafer, an upper surface of the edge ring faces and is spaced from a lower surface of the wafer to form a second annular channel. The first annular channel communicates with the second annular channel. A first width of the first annular channel in a radial direction of the base and a second width of the second annular channel in an axial direction of the base are smaller than or equal to twice a plasma sheath layer thickness generated when the semiconductor processing equipment performs a predetermined process.

Another aspect of the present disclosure provides semiconductor processing equipment. The semiconductor processing equipment includes a process chamber, an upper electrode mechanism, and a lower electrode mechanism. The upper electrode mechanism includes a showerhead and an upper electrode power supply. The showerhead is arranged at a top of the process chamber. The upper electrode power supply is electrically connected to the showerhead. The lower electrode mechanism includes a carrier device configured to carry a wafer and grounded. The carrier device includes a base body configured to carry a wafer. An outer diameter of the base body is smaller than a diameter of the wafer. The edge ring surrounds the base. An outer diameter of the edge ring is greater than the diameter of the wafer. An outer circumferential surface of the base body faces and is spaced from an inner circumferential surface of the edge ring to form a first annular channel. The first annular channel is configured to communicate with a gas supply system. When the base body carries the wafer, an upper surface of the edge ring faces and is spaced from a lower surface of the wafer to form a second annular channel. The first annular channel communicates with the second annular channel. A first width of the first annular channel in a radial direction of the base and a second width of the second annular channel in an axial direction of the base are smaller than or equal to twice a plasma sheath layer thickness generated when the semiconductor processing equipment performs a predetermined process.

The present disclosure includes the following beneficial effects.

In the carrier device of the semiconductor processing equipment of embodiments of the present disclosure, the outer circumferential surface of the base body can face and be spaced from the inner circumferential surface of the edge ring to form the first annular channel. When the base body carries the wafer, the upper surface of the edge ring can face and be spaced from the lower surface of the wafer to form the second annular channel. The first annular channel can communicate with the second annular channel and form the edge purge channel with the inlet channel of the first step member. When the edge purge channel blows gas, the back surface and side surface of the wafer can be purged, which prevents the thin film deposition on the back surface and side surface of the wafer. Thus, the uniformity of the thin film can be improved, the temperature of the edge ring can be reduced, and the thin film deposition on the surface of the edge ring can be reduced. Based on the edge purge channel, by causing the first width of the first annular channel in the radial direction of the base and the second width of the second annular channel in the axial direction of the base to be smaller than or equal to twice the plasma sheath layer thickness generated when the semiconductor processing equipment performs the predetermined processes. Thus, by ensuring the channel under the edge of the wafer to be smooth, the space of the edge purge channel can be reduced, which prevents the back surface of the wafer from discharging or sparking in the channel. Then, the process stability can be improved, and the particle contamination can be reduced.

### BRIEF DESCRIPTION OF THE DRAWINGS

FIG. 1 is a schematic structural diagram of semiconductor processing equipment according to some embodiments of the present disclosure.

FIG. 2 is a schematic enlarged diagram of area 1 in FIG. 1.

FIG. 3A is a schematic local cross-section diagram of a carrier device of semiconductor processing equipment according to some embodiments of the present disclosure.

FIG. 3B is a schematic local cross-section diagram of another carrier device of semiconductor processing equipment according to some embodiments of the present disclosure.

FIG. 3C is a schematic local cross-section diagram of another carrier device of semiconductor processing equipment according to some embodiments of the present disclosure.

FIG. 4A is a schematic structural diagram of another carrier device of semiconductor processing equipment according to some embodiments of the present disclosure.

FIG. 4B is a schematic diagram showing a dimension identification of the carrier device in FIG. 3A to FIG. 4A.

### DETAILED DESCRIPTION OF THE EMBODIMENTS

To cause those skilled in the art to better understand the technical solutions of the present disclosure, semiconductor processing equipment and a carrier device in the semiconductor process equipment of embodiments of the present disclosure are described in detail below in connection with the accompanying drawings.

Embodiments of the present disclosure provide semiconductor process equipment. The semiconductor process equipment can be, for example, the Metal-organic Chemical Vapor Deposition (MOCVD) equipment.

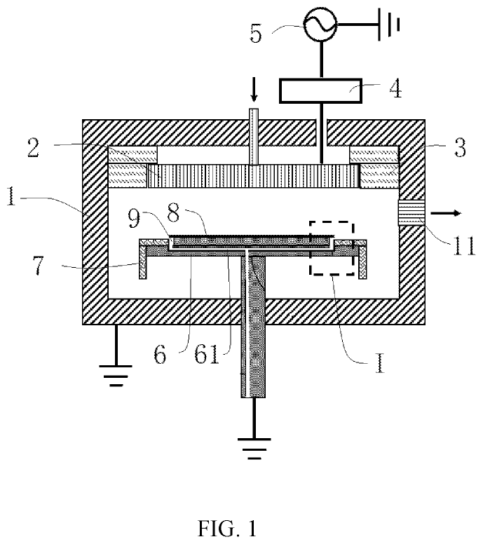

As shown in FIG. 1, taking the MOCVD equipment as an example, the equipment includes a reaction chamber including a chamber body 1 configured to perform processing on a wafer 8. A showerhead 2 is arranged at the top of the chamber body 1. The showerhead 2 can be configured to uniformly transfer a process gas to the reaction chamber and also serve as an upper electrode electrically connected to a radio frequency (RF) power source 5 (common frequencies include 13.56 MHz, 2 MHz, and 400 kHz) through a matcher 4. The chamber body 1 can be made of a metal material and be grounded. An insulation liner 3 is also arranged inside the chamber body 1. The insulation liner 3 can surround the showerhead 2 to isolate the high-voltage showerhead 2 from the chamber body 1 to realize electrical insulation. In addition, an exhaust port 11 is arranged at the chamber body 1. The exhaust port 11 can be configured to communicate with a vacuum system (not shown in the figure) to realize chamber evacuation and pressure control.

A carrier device is arranged in the chamber body 1. The carrier device includes a base 6 and an edge ring 7 surrounding the base 6. The base 6 can be configured to carry the wafer 8 and can also function as a heater to heat the wafer 8 to a temperature required for thin film deposition. The base 6 can be made of a metal material (e.g., aluminum or stainless steel) and can be grounded. The edge ring 7 can be made of a metal material (e.g., aluminum or stainless steel) and can be configured to prevent a thin film from depositing on the surface of the base 6 (including the back surface) during the process.

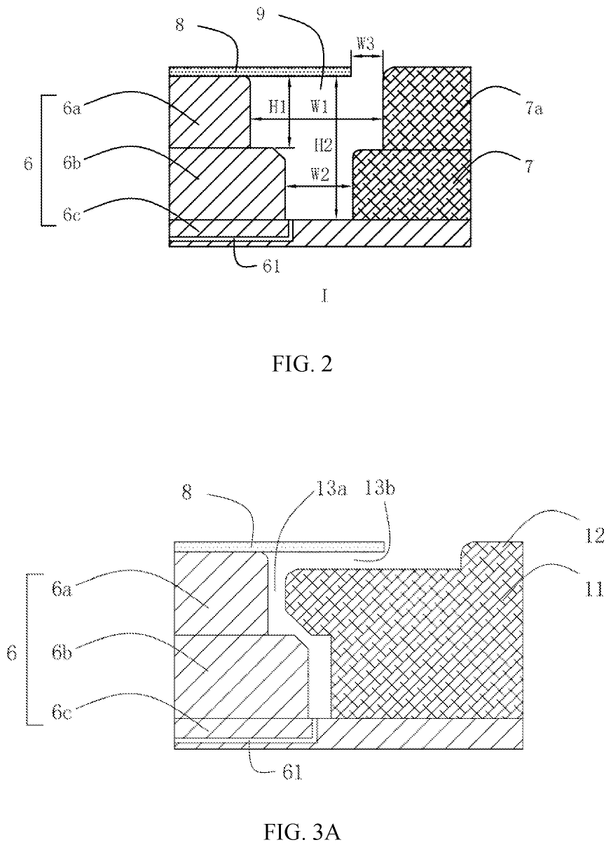

As shown in FIG. 2, in the carrier device, the base 6 includes a base body configured to carry the wafer 8 and a first step member 6c arranged at the bottom of the base body and protruding relative to an outer peripheral surface of the base body. The edge ring 7 is arranged at the first step member 6c. The outer diameter of the base body can be smaller than the diameter of the wafer 8, and the outer diameter of the edge ring 7 can be larger than the diameter of the wafer 8.

In some embodiments, the surface of the edge ring 7 (e.g., the upper surface of the edge ring 7 in FIG. 2) includes a first annular protrusion 7a. The surface of the first annular protrusion 7a is flush with the surface of the wafer 8. In some embodiments, the outer peripheral surface of the first annular protrusion 7a is flush with the outer peripheral surface of the edge ring 7. The diameter of the inner peripheral surface of the first annular protrusion 7a can be greater than the diameter of the inner peripheral surface of the edge ring 7.

In some embodiments, the base body includes a main body 6a and a second annular protrusion 6b protruding from the outer peripheral surface of the main body 6a. In some embodiments, as shown in FIG. 2, the main body 6a and the second annular protrusion 6b are in a split structure. The main body 6a is stacked on the upper surface of the second annular protrusion 6b. The diameter of the outer peripheral surface of the second annular protrusion 6b is greater than the diameter of the outer peripheral surface of the main body 6a. Thus, a part of the second annular protrusion 6b can protrude from the outer peripheral surface of the main body 6a. However, embodiments of the present disclosure are not limited to this. In some embodiments, the main body 6a and the second annular protrusion 6b can also be in an integral structure.

Further, as shown in FIG. 2, a radial distance between the outer peripheral surface of the main body 6a and the inner peripheral surface of the first annular protrusion 7a is W1. A radial distance between the outer peripheral surface of the second annular protrusion 6b and the inner peripheral surface of the edge ring 7 is W2. When the wafer 8 is placed on the upper surface of the main body 6a, the edge of the wafer 8 protrudes relative to the outer peripheral surface of the main body 6a, and a radial distance between the side surface of the wafer 8 and the inner peripheral surface of the first annular protrusion 7a is W3. A vertical distance between the back surface of the wafer 8 and the upper surface of the second annular protrusion 6b is H1. A vertical distance between the back surface of the wafer 8 and the upper surface of the first step member 6c is H2. The base 6, the edge ring 7, and the wafer 8 can enclose to form an annular narrow gap 9. The annular narrow gap 9 can be used as an edge purge channel and can communicate with an inlet channel 61 arranged at the first step member 6c. The inlet channel 61 can be configured to communicate with a gas supply system. The gas provided by the gas supply system can pass through the inlet channel 61 and the edge purge channel to flow into the reaction chamber.

During the deposition process, the inlet channel 61 can be configured to blow the gas into the edge purge channel. The gas can blow out from the edge of the wafer 8 through the edge purge channel, which prevents the thin film from being deposited on the back surface and edge of the wafer 8. During performing a plasma processing process, the inlet channel 61 does not blow a gas. However, since the edge purge channel communicates with the reaction chamber, the insulated wafer 8 can be charged in the plasma environment to form a high potential, while the edge ring 7 and the base 6 are both grounded at zero potential. Thus, a voltage difference can exist between the wafer 8 and the edge ring 7 and the base 6. Thus, sparks need to be prevented between the edge ring 7 and the bottom surface and side surface of the wafer 8. However, in the sizes of the base 6, the edge ring 7, and the wafer 8, H1, H2, W1, and W2 can be greater than 1.3 mm. H2 and W1 can be close to 4 mm, which causes the internal space of the edge purge channel to be large. When the semiconductor processing equipment performs a predetermined process such as the plasma processing process, as the RF power applied to the reaction chamber increases, the process pressure becomes higher, the voltage on the wafer surface increases, the thickness of the plasma sheath layer generated by the process becomes smaller (can be reduced to below 500 micrometers). Thus, discharging can easily occur in the edge purge channel with a large space, which can affect the process stability and cause particle contamination. In addition, since W3 is smaller than 1 mm, the distance between the edge of the wafer 8 and the first annular protrusion can be close. Thus, the electric field strength between the edge of the wafer and the first annular protrusion can be high, and the arc discharging can easily occur.

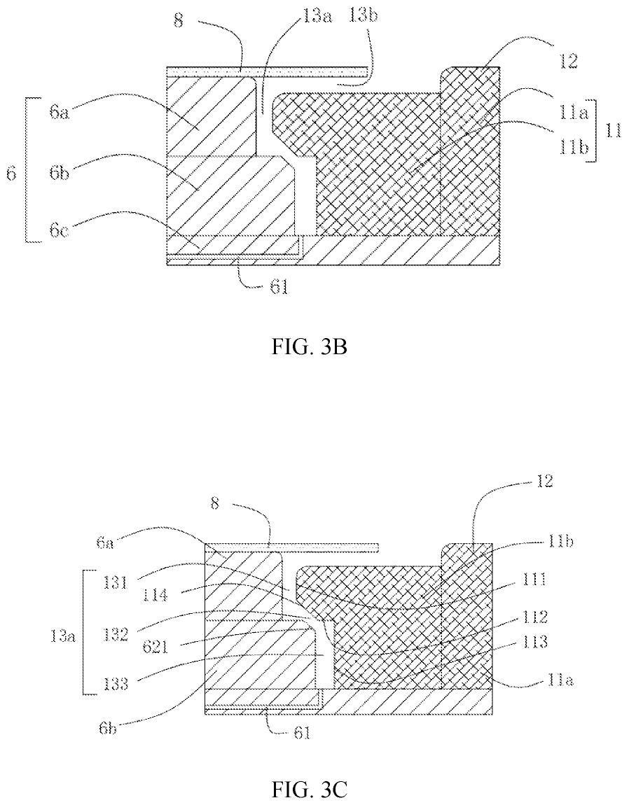

To address the above issues, embodiments of the present disclosure provide a carrier device in the semiconductor process equipment. The carrier device can be, for example, applied to the MOCVD equipment. In some embodiments, as shown in FIGS. 3A and 3B, the carrier device includes a base 6 and an edge ring 11 surrounding the base 6. The base 6 can be configured to carry a wafer 8 and also function as a heater to heat the wafer 8 to the temperature required for thin film deposition. The base 6 can be made of a metal material (e.g., aluminum or stainless steel) and be grounded. The edge ring 11 can be made of a metal material (e.g., aluminum or stainless steel) and be configured to prevent film deposition on the surface of the base 6 (including the backside).

The base 6 includes a base body and a first step member 6c arranged at the bottom of the base body and protruding relative to the outer peripheral surface of the base body. In some embodiments, the base body includes a main body 6a and a second annular protrusion 6b protruding from the outer peripheral surface of the main body 6a. In some embodiments, the structure of the base body is not limited to this. In some embodiments, the base body may not be arranged at the second annular protrusion 6b, which is not limited in embodiments of the present disclosure.

The edge ring 11 is arranged at the first step member 6c. The outer diameter of the base body (including the main body 6a and the second annular protrusion 6b) is smaller than the diameter of the wafer 8, and the outer diameter of the edge ring 11 is larger than the diameter of the wafer 8. Moreover, the outer peripheral surface of the base body faces and is spaced from the inner peripheral surface of the edge ring 11 to form a first annular channel 13a. When the base body carries the wafer 8, the upper surface of the edge ring 11 faces and is spaced from the back surface (i.e., lower surface) of the wafer 8 to form a second annular channel 13b. The first annular channel 13a can communicate with the second annular channel 13b, and an inlet channel 61 is arranged at the first step member 6c. An outlet end of the inlet channel 61 can communicate with the first annular channel 13a. The first annular channel 13a and the second annular channel 13b can form the edge purge channel. During the deposition process, the inlet channel 61 can blow the gas into the edge purge channel, and the gas can pass through the edge purge channel to blow out from the edge of the wafer 8, which prevents the thin film from being deposited on the back surface and the edge of the wafer 8. During the plasma processing process, the inlet channel 61 does not blow gas.

In some embodiments, the first step member 6c can be saved. Thus, the edge ring 11 can be fixed to the base 6 relatively in any other suitable manner, and the first annular channel 13a can communicate with the gas supply system directly or through another pipe structure.

In a plasma, since a mass of an electron is smaller than a mass of an ion, and the moving speed of the electron is faster than the moving speed of the ion, the electron can first be adhered to the surface of the electrode to form a negative potential. The negatively charged electrode can repel electrons and attract ions to form an area near the electrode with an electron density smaller than an ion density. The area can be referred to as a plasma sheath layer, and the thickness of the area can be referred to as a plasma sheath layer thickness. In a limited area, the plasma can form a “sandwich” structure of sheath-neutral plasma-sheath. When the distance between electrodes (or walls) is less than twice the plasma sheath layer thickness, only overlapping plasma sheath layers can fit between the electrodes, and the neutral plasma area can be exhausted. Thus, free electrons can be significantly reduced, which causes a lack of collision ionization and causes the discharge to be impossible to be maintained. Thus, in a plasma environment, the width of the slot and the diameter of the pipe may need to be smaller than twice the plasma sheath layer thickness to prevent the discharge. The two members with significant potential differences can have a stronger electric field with a smaller distance. Thus, sparks can occur more easily. Thus, the members may need to maintain a sufficient insulation distance.

Based on the above principle, to prevent sparks between the edge ring 11 and the bottom surface and side surface of the wafer 8, a first width of the first annular channel 13a in a radial direction of the base 6 and a second width of the second annular channel 13b in an axial direction of the base 6 can be both less than or equal to twice of the plasma sheath layer thickness generated during the predetermined process (e.g., plasma processing process) performed by the semiconductor process equipment. Thus, the channel under the edge of the wafer can be ensured to be unblocked, the space of the edge purge channel can be reduced, which can suppress the occurrence of discharge or sparks on the back surface of the wafer 8 in the channel. Therefore, the process stability can be improved, and the particle contamination can be reduced to cause the process chamber to be applied under high power and high-pressure conditions and expand the process window.

In some embodiments, as shown in FIG. 3A, a first annular protrusion 12 protrudes from the surface of the edge ring 11 (e.g., the upper surface of the edge ring 11 in FIG. 3A). The surface of the first annular protrusion 12 is leveled with the surface of the wafer 8 to ensure the electric field to be uniformly distributed above the wafer. The radial distance between the inner peripheral surface of the first annular protrusion 12 and the side surface of the wafer 8 can be greater than twice the plasma sheath layer thickness. Thus, the plasma can stably discharge in the groove formed between the edge of the wafer 8 and the inner peripheral surface of the first annular protrusion 12. The distance can be ensured to be sufficient to lower the electric field strength in the space between the wafer 8 and the edge ring 11 with different potentials. Thus, the arc discharging can be avoided. In some embodiments, the distance can be greater than 1 mm. In some other embodiments, the outer peripheral surface of the first annular protrusion 12 can be coplanar with the outer peripheral surface of the edge ring 11.

In some embodiments, as shown in FIG. 3B, the edge ring 11 includes an annular body 11a and a channel member 11b connected to each other. The outer peripheral surface of the base body can be spaced from the inner peripheral surface of the annular body 11a, and the channel member 11b is arranged between thereof. The outer peripheral surface of the channel member 11b abuts against the inner peripheral surface of the annular body 11a. The inner peripheral surface of the channel member 11b faces and is spaced from the outer peripheral surface of the base body to form the first annular channel 13a. A surface of the channel member 11b facing the wafer 8 faces and is spaced from the surface of the wafer 8 facing the channel member 11b to form the second annular channel 13b. Moreover, the annular body 11a includes a protrusion protruding from the surface of the channel member 11b. The protrusion can be the first annular protrusion 12. By arranging the channel member 11b in the gap between the outer peripheral surface of the base body and the inner peripheral surface of the annular body 11a, the space in the gap can be reduced to cause the first width of the first annular channel 13a in the radial direction of the base 6 and the second width of the second annular channel 13b in the radial direction of the base 6 to be smaller or equal to twice of the plasma sheath layer thickness. Moreover, the channel member 11b abuts against the inner peripheral surface of the annular body 11a. By determining the structure of the base body and the annular body 11a, the structure of the channel member 11b can be flexibly designed to satisfy the requirement of suppressing the discharging or sparks of the back surface of the wafer in the channel, and the convenience of installation can be improved.

In some embodiments, the axial cross-sectional shape of the first annular channel 13a can be in a bent line shape. Thus, a “maze-like” edge purge channel can be formed, which can block the plasma from entering to a certain degree to further suppress the discharge or sparks of the back surface of the wafer in the channel.

The first annular channel 13a in the bent line shape can include a plurality of structures. For example, in some embodiments, as shown in FIG. 3C, the base body includes a main body 6a and a second annular protrusion 6b protruding from the outer peripheral surface of the main body 6a. In some embodiments, the outer peripheral surface of the second annular protrusion 6b can be arranged under the outer peripheral surface of the main body 6a. The upper end surface of the second annular protrusion 6b is connected between the outer peripheral surface of the second annular protrusion 6b and the outer peripheral surface of the main body 6a. Furthermore, In some embodiments, the main body 6a and the second annular protrusion 6b can have separate structures, and the main body 6a is stacked on the upper surface of the second annular protrusion 6b. The diameter of the outer peripheral surface of the second annular protrusion 6b can be greater than the diameter of the outer peripheral surface of the main body 6a to cause a part of the second annular protrusion 6b to protrude from the outer peripheral surface of the main body 6a. However, embodiments of the present disclosure are not limited to this. In some other embodiments, the main body 6a and the second annular protrusion 6b can also have an integral structure.

Moreover, the inner peripheral surface of the channel member 11b includes a first sub-surface 111, a second sub-surface 112, and a third sub-surface 113. The first sub-surface 111 faces and is spaced from the outer peripheral surface of the main body 6a to form the first annular sub-channel 131. The second sub-surface 112 and the second protrusion 6b face and are spaced from the end surface of the main body 6a (i.e., the upper end surface of the second annular protrusion 6b in FIG. 3C) to form the second annular sub-channel 132. The third sub-surface 113 faces and is spaced from the outer peripheral surface of the second annular protrusion 6b to form a third annular sub-channel 133. The first annular sub-channel 131, the second annular sub-channel 132, and the third annular sub-channel 133 are connected in sequence in the direction close to an outlet end of the inlet channel 61. Thus, the first annular sub-channel 131, the second annular sub-channel 132, and the third annular sub-channel 133, together with the second annular channel 13b, form a four-segment “maze-like” edge purge channel. The “maze-like” channel can partially block the entry of the plasma to further suppress the discharge or sparks of the back surface of the wafer in the channel.

In some embodiments, as shown in FIG. 3C, the end surface of the second annular protrusion 6b facing the wafer 8 forms a first chamfered inclined surface 621 between the end surface and the outer peripheral surface of the second annular protrusion 6b. The second sub-surface 112 forms a second chamfered inclined surface 114 with the first sub-surface 111. The second chamfered inclined surface 114 faces and is spaced from the first chamfered inclined surface 621. With the first chamfered inclined surface 621 and the second chamfered inclined surface 114, a right angle curve can be prevented from being formed in the edge purge channel. The gas can flow smoothly, and the possibility of the tip discharge can be reduced. In some embodiments, any other chamfered structure can be adopted, which is not limited in embodiments of the present disclosure.

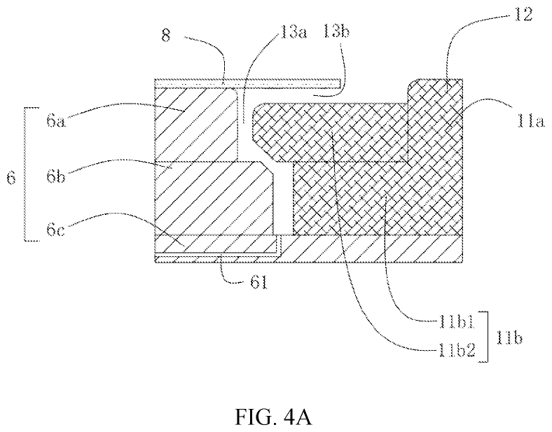

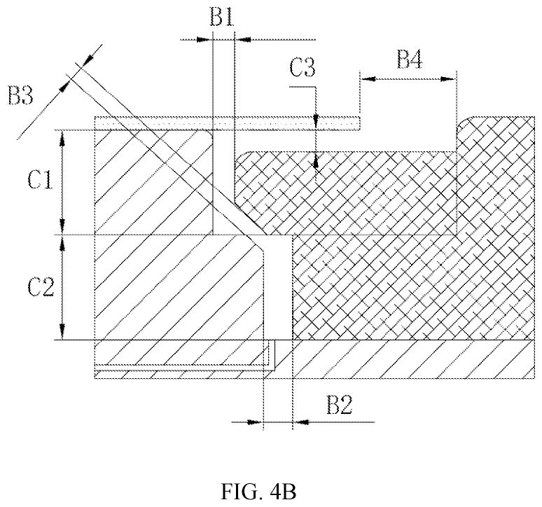

In some embodiments, as shown in FIGS. 3B and 3C, the channel member 11b has an integral structure and forms a separate structure with the annular body 11a. However, embodiments of the present disclosure are not limited to this. For example, as shown in FIG. 4A, the channel member 11b includes a first ring 11b1 and a second ring 11b2 stacked from bottom to top in sequence. The inner peripheral surface of the second ring 11b2 is the first sub-surface 111 shown in FIG. 3C. The inner peripheral surface of the first ring 11b1 is the third sub-surface 113 shown in FIG. 3C. The second ring 11b2 has a protrusion protruding from the inner peripheral surface of the first ring 11b1. The end surface of the protrusion of the second ring 11b2 facing the first ring 11b1 is the second sub-surface 112 shown in FIG. 3C. That is, the channel member 11b is formed by the first ring 11b1 and the second ring 11b2, which improves the processing convenience and the design flexibility of the edge purge channel.

In some embodiments, the first ring 11b1 and the annular body 11a have an integral structure. The second ring 11b2 has separate structures with both the first ring 11b1 and the annular body 11a. By causing the first ring 11b1 and the annular body 11a to have the integral structure, the structural stability can be improved. By causing the second ring 11b2 to have separate structures from the first ring 11b1 and the annular body 11a, the processing convenience and the design flexibility of the edge purge channel can be improved.

FIG. 4B is a schematic diagram illustrating the size marks of the carrier device in FIGS. 3A to 4A. In connection with FIG. 3C and FIG. 4B, the first width of the first annular channel 13a in the radial direction of the base 6 and the second width of the second annular channel 13b in the radial direction of the base 6 are smaller than or equal to twice the plasma sheath layer thickness generated when the semiconductor processing equipment performs the predetermined processes (e.g., the plasma processing process). In some embodiments, a radial distance between the first sub-surface 111 and the outer peripheral surface of the main body 6a, i.e., the radial distance B1 of the first annular sub-channel 131, is less than or equal to twice the plasma sheath layer thickness. A distance between the first chamfered inclined surface 621 and the second chamfered inclined surface 114, i.e., the distance B3 of the second annular sub-channel 132, is less than or equal to twice the plasma sheath layer thickness. A radial distance between the third sub-surface 113 and the outer peripheral surface of the second annular protrusion 6b, i.e., the radial distance B2 of the third annular sub-channel 133, is less than or equal to twice the plasma sheath layer thickness. In addition, when the base body carries the wafer 8, the vertical distance between the upper surface of the channel member 11b and the back surface (i.e., bottom surface) of the wafer 8, i.e., the second width C3 of the second annular channel 13b in the axial direction of the base 6, is smaller than or equal to twice of the plasma sheath layer thickness. Thus, the discharge and sparks of the back surface of the wafer can be suppressed in the channel to improve the process stability and reduce particle contamination.

In some embodiments, the radial distance B4 between the inner peripheral surface of the first annular protrusion 12 and the side surface of the wafer 8 can be greater than twice the plasma sheath layer thickness. Thus, the plasma can stably discharge in the groove formed between the edge of the wafer 8 and the inner peripheral surface of the first annular protrusion 12, and the radial distance B4 can be sufficient to reduce the spatial electric field between the wafer 8 and the edge ring 11 with different potentials to further prevent the arc discharge. In some embodiments, the radial distance B4 can be greater than 1 mm.

Furthermore, the vertical height C1 of the main body 6a in the base body and the vertical height C2 of the second annular protrusion 6b can be set as needed.

In some embodiments, the surface of the edge ring 11 exposed in the plasma environment can be a surface after the insulation processing. Thus, the upper surface of the edge ring can be charged in the plasma environment to form a negative potential. Thus, the potential of the upper surface of the edge ring can be consistent with the potential of the upper surface of the wafer, or the voltage difference between the upper surface of the edge ring and the upper surface of the wafer can be small. Thus, the probability of discharging can be further reduced. The insulation processing can be performed in a plurality of methods, e.g., surface oxidation or ceramic coating.

In some embodiments, edge corners of the base 6 and the edge ring 11 can be rounded corners. Thus, the probability of the occurrence of the tip discharge can be reduced. The combination of rounded processing and surface insulation processing can be used to suppress the arc discharge between the wafer 8 and the edge ring 11.

In some embodiments, the inlet channel 61 can include a plurality of outlets, which are distributed uniformly in a circumferential direction along the first annular channel 13a. Thus, the gas can uniformly enter the first annular channel 13a to improve the process uniformity. In some embodiments, the inlet channel 61 can include a plurality of vertical holes and a plurality of horizontal channels. Outlets of the plurality of vertical holes can be used as the outlets of the inlet channel 61, which communicate with the first annular channel 13a, and can be uniformly distributed along the circumferential direction of the first annular channel 13a. the inlets of the vertical holes can communicate with outlets of the horizontal channels in a one-to-one correspondence. The inlets of the horizontal channels can converge at the center position of the base 6 and can communicate with the gas supply system.

In some embodiments, the base 6 can be made of a metal material or an insulation material. The insulation ring 11 can be made of a metal material or an insulation material. For the base 6 and the insulation ring 11 made of the metal material, the installation of the base 6 and the insulation ring 11 needs to consider thermal expansion. Thus, the width of the edge purge channel needs to be smaller than twice the plasma sheath layer thickness and also reserves a certain space for the thermal expansion of the base 6 and the insulation ring 11. In addition, if the deposited thin film is a metal material, the base 6 and the insulation ring 11 can be made of the metal material. If the deposited thin film is the insulation material (e.g., silicone oxide), the base 6 and the insulation ring 11 can be made of the insulation material (e.g., ceramic).

In summary, in the carrier device of the semiconductor processing equipment of embodiments of the present disclosure, the outer circumferential surface of the base body can face and be spaced from the inner circumferential surface of the edge ring to form the first annular channel. When the base body carries the wafer, the upper surface of the edge ring can face and be spaced from the lower surface of the wafer to form the second annular channel. The first annular channel can communicate with the second annular channel and form the edge purge channel with the inlet channel of the first step member. When the edge purge channel blows gas, the back surface and side surface of the wafer can be purged, which prevents the thin film deposition on the back surface and side surface of the wafer. Thus, the uniformity of the thin film can be improved, the temperature of the edge ring can be reduced, and the thin film deposition on the surface of the edge ring can be reduced. Based on the edge purge channel, by causing the first width of the first annular channel in the radial direction of the base and the second width of the second annular channel in the axial direction of the base to be smaller than or equal to twice the plasma sheath layer thickness generated when the semiconductor processing equipment performs the predetermined processes. Thus, by ensuring the channel under the edge of the wafer to be smooth, the space of the edge purge channel can be reduced, which prevents the back surface of the wafer from discharging or sparking in the channel. Then, the process stability can be improved, and the particle contamination can be reduced.

As another technical solution, embodiments of the present disclosure provide semiconductor processing equipment. The semiconductor processing equipment is similar to the semiconductor processing equipment shown in FIG. 1 and includes the process chamber formed by the chamber body 1, the upper electrode mechanism, and a lower electrode mechanism. The upper electrode mechanism can include the showerhead 2 arranged at the top in the process chamber and the upper electrode power supply (e.g., RF power supply 5) electrically connected to the showerhead 2. The lower electrode, for example, can include the carrier device configured to carry the wafer 8. The carrier device can be the carrier device of embodiments of the present disclosure. By taking the carrier device shown in FIG. 3 as an example, the carrier device includes the base 6 and the edge ring 11 surrounding the base 6. The base 6 can be grounded and can be used as a heater to heat the wafer 8 to cause the wafer 8 to reach the temperature for the thin film deposition. The base 6 can be made of the metal material (e.g., aluminum or stainless steel) and can be grounded. The edge ring 11 can be made of the metal material (e.g., aluminum or stainless steel) and can be configured to prevent the thin film from being deposited on the surface of the base 6 (including the back surface) during the processing process.

In some embodiments, the semiconductor processing equipment can be metal-organic chemical vapor deposition equipment.

In the semiconductor processing equipment of embodiments of the present disclosure, with the carrier device of embodiments of the present disclosure, the channel under the edge of the wafer can be smooth, and the back surface of the wafer can be prevented from discharging or sparking in the channel. Thus, the process stability can be improved, and the particle contamination can be reduced.

The above embodiments are merely exemplary embodiments of embodiments of the present disclosure. The present disclosure is not limited to this. For those skilled in the art, modifications and improvements can be made without departing from the spirit and essence of the present disclosure. These modifications and improvements are within the scope of the present disclosure.

What is claimed is:

1. A carrier device in semiconductor processing equipment comprising:
a base including:
a base body configured to carry a wafer, an outer diameter of the base body being smaller than a diameter of the wafer; and
an edge ring surrounding the base, an outer diameter of the edge ring being greater than the diameter of the wafer;
wherein:
an outer circumferential surface of the base body faces and is spaced from an inner circumferential surface of the edge ring to form a first annular channel;
the first annular channel is configured to communicate with a gas supply system;
when the base body carries the wafer, an upper surface of the edge ring faces and is spaced from a lower surface of the wafer to form a second annular channel;
the first annular channel communicates with the second annular channel;
a first width of the first annular channel in a radial direction of the base and a second width of the second annular channel in an axial direction of the base are smaller than or equal to twice a plasma sheath layer thickness generated when the semiconductor processing equipment performs a predetermined process.

2. The carrier device according to claim 1, wherein:
a first annular protrusion protrudes from a surface of the edge ring;
a surface of the first annular protrusion is flush with the surface of the wafer;
a radial distance exists between an inner circumferential surface of the first annular protrusion and the side surface of the wafer; and
the radial distance is greater than twice the plasma sheath layer thickness.

3. The carrier device according to claim 2, wherein the edge ring includes:
an annular body and a channel member connected to each other, wherein:
an outer circumferential surface of the base body is spaced from an inner circumferential surface of the annular body;
the channel member is arranged between the outer circumferential surface of the base body and the inner circumferential surface of the annular body;
an outer circumferential surface of the channel member abuts against the inner circumferential surface of the annular body;
an inner circumferential surface of the channel member faces and is spaced from the outer circumferential surface of the base body to form the first annular channel;
a surface of the channel member facing the wafer faces and is spaced from the surface of the wafer facing the channel member to form the second annular channel; and
the annular body includes a protrusion protruding relative to a surface of the channel member, and the protrusion is the first annular protrusion.

4. The carrier device according to claim 3, wherein an axial cross-sectional shape of the first annular channel is a bent line shape.

5. The carrier device according to claim 4, wherein:
the base body includes a body and a second annular protrusion protruding from an outer circumferential surface of the body;
the inner circumferential surface of the channel member includes a first sub-surface, a second sub-surface, and a third sub-surface;
the first sub-surface faces and is spaced from the outer circumferential surface of the body to form a first annular sub-channel;
the second sub-surface faces and is spaced from an end surface of the second annular protrusion facing the body to form a second annular sub-channel;
the third sub-surface faces and is spaced from the outer circumferential surface of the second annular protrusion to form a third annular sub-channel; and
the first annular sub-channel, the second annular sub-channel, and the third annular sub-channel communicate with each other in sequence.

6. The carrier device according to claim 5, wherein:
a first chamfered inclined surface is formed between an end surface of the second annular protrusion facing the wafer and an outer circumferential surface of the second annular protrusion;
a second chamfered inclined surface is formed between the second sub-surface and the first sub-surface; and
the second chamfered inclined surface faces and is spaced from the first chamfered inclined surface.

7. The carrier device according to claim 5, wherein:
the channel member includes a first ring and a second ring stacked in sequence from bottom to top, wherein:
an inner circumferential surface of the second ring is a first sub-surface;
an inner circumferential surface of the first ring is a third sub-surface;
the second ring includes a protrusion protruding relative to the inner circumferential surface of the first ring; and
an end surface of the protrusion facing the first ring is the second sub-surface.

8. The carrier device according to claim 7, wherein:
the first ring and the annular body have an integral structure; and
the second ring is separate from the first ring and the annular body.

9. The carrier device according to claim 1, wherein:
the base includes a first step member arranged at bottom of the base body and protruding relative to the outer circumferential surface of the base body and including an inlet channel;
the edge ring is arranged at the first step member;
an outlet end of the inlet channel communicates with the first annular channel; and
an inlet end of the inlet channel is configured to communicate with the gas supply system.

10. The carrier device according to claim 1, wherein the first width of the first annular channel in the radial direction of the base and the second width of the second annular channel in the axial direction of the base are smaller than or equal to 1 mm.

11. The carrier device according to claim 1, wherein a surface of the edge ring exposed in a plasma environment is a surface that is processed with insulation.

12. The carrier device according to claim 1, wherein edge corners of the base and the edge ring are rounded corners.

13. Semiconductor processing equipment comprising:
a process chamber,
an upper electrode mechanism including:
a showerhead arranged at a top in the process chamber; and
an upper electrode power supply electrically connected to the showerhead; and
a lower electrode mechanism including a carrier device configured to carry a wafer and grounded, including:
a base including:
a base body configured to carry a wafer, an outer diameter of the base body being smaller than a diameter of the wafer; and
an edge ring surrounding the base, an outer diameter of the edge ring being greater than the diameter of the wafer;
wherein:
an outer circumferential surface of the base body faces and is spaced from an inner circumferential surface of the edge ring to form a first annular channel;
the first annular channel is configured to communicate with a gas supply system;
when the base body carries the wafer, an upper surface of the edge ring faces and is spaced from a lower surface of the wafer to form a second annular channel;
the first annular channel communicates with the second annular channel;
a first width of the first annular channel in a radial direction of the base and a second width of the second annular channel in an axial direction of the base are smaller than or equal to twice a plasma sheath layer thickness generated when the semiconductor processing equipment performs a predetermined process.

14. The equipment according to claim 13, wherein:
a first annular protrusion protrudes from a surface of the edge ring;
a surface of the first annular protrusion is flush with the surface of the wafer;
a radial distance exists between an inner circumferential surface of the first annular protrusion and the side surface of the wafer; and
the radial distance is greater than twice of the plasma sheath layer thickness.

15. The equipment according to claim 14, wherein the edge ring includes:
an annular body and a channel member connected to each other, wherein:
an outer circumferential surface of the base body is spaced from an inner circumferential surface of the annular body;
the channel member is arranged between the outer circumferential surface of the base body and the inner circumferential surface of the annular body;
an outer circumferential surface of the channel member abuts against the inner circumferential surface of the annular body;
an inner circumferential surface of the channel member faces and is spaced from the outer circumferential surface of the base body to form the first annular channel;
a surface of the channel member facing the wafer faces and is spaced from the surface of the wafer facing the channel member to form the second annular channel; and
the annular body includes a protrusion protruding relative to a surface of the channel member, and the protrusion is the first annular protrusion.

16. The equipment according to claim 15, wherein an axial cross-sectional shape of the first annular channel is a bent line shape.

17. The equipment according to claim 16, wherein:
the base body includes a body and a second annular protrusion protruding from an outer circumferential surface of the body;
the inner circumferential surface of the channel member includes a first sub-surface, a second sub-surface, and a third sub-surface;
the first sub-surface faces and is spaced from the outer circumferential surface of the body to form a first annular sub-channel;
the second sub-surface faces and is spaced from an end surface of the second annular protrusion facing the body to form a second annular sub-channel;
the third sub-surface faces and is spaced from the outer circumferential surface of the second annular protrusion to form a third annular sub-channel; and
the first annular sub-channel, the second annular sub-channel, and the third annular sub-channel communicate with each other in sequence.

18. The equipment according to claim 17, wherein:
a first chamfered inclined surface is formed between an end surface of the second annular protrusion facing the wafer and an outer circumferential surface of the second annular protrusion;
a second chamfered inclined surface is formed between the second sub-surface and the first sub-surface; and
the second chamfered inclined surface faces and is spaced from the first chamfered inclined surface.

19. The equipment according to claim 17, wherein:
the channel member includes a first ring and a second ring stacked in sequence from bottom to top, wherein:
an inner circumferential surface of the second ring is a first sub-surface;
an inner circumferential surface of the first ring is a third sub-surface;
the second ring includes a protrusion protruding relative to the inner circumferential surface of the first ring; and
an end surface of the protrusion facing the first ring is the second sub-surface.

20. The equipment according to claim 19, wherein:
the first ring and the annular body have an integral structure; and
the second ring is separate from the first ring and the annular body.
